(19) United States
(12) Patent Application Publication
(10) Pub. No.: US 2011/0073969 A1
(43) Pub. Date: Mar. 31, 2011

(54) SENSOR SYSTEM AND METHOD FOR MANUFACTURING SAME

(76) Inventors: Hubert Benzel, Pliezhausen (DE); Roland Guenschel, Wannweil (DE)

(21) Appl. No.: 12/893,340

(22) Filed: Sep. 29, 2010

(30) Foreign Application Priority Data
Sep. 30, 2009 (DE) 10 2009 045 164.1

(51) Int. Cl. H01L 29/84; H01L 21/50

(52) U.S. Cl. 257/419; 438/51; 257/E29.324; 257/E21.499

(57) ABSTRACT

An assembly and connection technology for a sensor system, including a sensor element having circuit elements integrated into the top side and a carrier for the sensor element, which is simple and robust and which does not require any further packaging measures for protecting the circuit elements and electrical terminals of the sensor elements after the isolation of the sensor elements. For this purpose, the carrier is provided with through contacts. In addition, the sensor element is installed in flip-chip technology on the carrier, so that the top side of the sensor element is at least regionally capped by the carrier and the circuit elements of the sensor element can be electrically contacted from the rear side of the carrier via the through contacts.

### RELATED APPLICATION INFORMATION

The present application claims priority to and the benefit of German patent application no. 10 2009 045 164.1, which was filed in Germany on Sep. 30, 2009, the disclosure of which is incorporated herein by reference.

### FIELD OF THE INVENTION

The present invention relates to a sensor system, which is intended for use in an aggressive measuring environment. It includes a sensor element having circuit elements integrated into the top side and a carrier for the sensor element. A sensor system of this type may thus include a sensor element, into whose surface entire circuit parts of an analysis circuit are integrated, or also a sensor element without an analysis circuit, in whose surface, for example, only piezoresistors for measured value detection having supply lines and terminal pads are implemented. Furthermore, the present invention relates to a method for manufacturing such a sensor system.

### BACKGROUND INFORMATION

FIG. 1 shows a sensor system 10 for absolute pressure detection, as is known from practice. This sensor system 10 includes a micromechanical sensor element 1, in whose top side a diaphragm 11 is implemented over a cavern 12. Cavern 12 is closed in a pressure-tight manner on the rear. For this purpose, sensor element 1 was bonded to a glass carrier 2. A defined reference pressure for the measurement pressure, which acts on the front side of diaphragm 11, prevails within cavern 12. The resulting diaphragm deformations are detected with the aid of piezoresistive transducer elements 13, which are integrated into the diaphragm front side. In the exemplary embodiment shown here, the composite made of glass carrier 2 and sensor element 1 was installed on a circuit board 3 using an adhesive layer 4. The electrical connection between sensor element 1 and circuit board 3 is formed by bonding wires 5, which are led from the top side of sensor element 1 to circuit board 3. In order to protect circuit elements 13 in the surface of sensor element 1 and bonding wires 5 against aggressive measuring media, sensor element 1 is embedded together with bonding wires 5 in a gel layer 7, which is implemented inside a gel ring 6 on circuit board 3.

Both the assembly and the installation of the known sensor system have proven to be problematic in practice.

The configuration of the circuit elements and the electrical terminals of the sensor element on the top side of the sensor element, which faces toward the measurement medium, requires that the electrical connection lines also come into contact with the measurement medium, if additional protective measures are not taken, such as embedding in a suitable protective gel. This form of “packaging” may only be implemented individually after the isolation of the sensor systems and after their installation.

The known sensor system may only be used in a limited pressure range because of the above-described assembly and connection technology. In addition, the known sensor system has a comparatively high lateral acceleration sensitivity because of the additional mass of the protective gel on the sensor diaphragm. Moreover, the media resistance and the temperature resistance of the sensor system are substantially a function of the type, composition, and resistance of the gel passivation.

### SUMMARY OF THE INVENTION

The exemplary embodiments and/or exemplary methods of the present invention provide an assembly and connection technology for a sensor system of the type cited at the beginning; which is simple and robust and, after the isolation of the sensor elements, does not require any further packaging measures for protecting the circuit elements and electrical terminals of the sensor elements.

For this purpose, the carrier of the sensor system according to the present invention is provided with through contacts and the sensor element is installed in flip-chip technology on the carrier, so that the top side of the sensor element is at least regionally capped by the carrier and the circuit elements of the sensor element may be electrically contacted from the rear side of the carrier via the through contacts.

Accordingly, a carrier substrate having embedded through contacts and flip-chip connection technology is essential according to the present invention, and is used to create both a fixed composite made of sensor element and carrier and also a reliable electrical contact of the sensor element. According to the invention, the carrier thus has at least three functions. As in the related art, the carrier is used as an installation base of the sensor system. Furthermore, the carrier forms a cap for the sensor element surface and thus protects the circuit elements and any micromechanical structures in the surface of the sensor element. In addition, the sensor element is electrically contacted via the through contacts implemented in the carrier.

Fundamentally, there are various possibilities for the implementation of a sensor system according to the present invention with respect to the function of the sensor element. A sensor system according to the present invention may thus be designed, for example, as an acceleration sensor. The implementation of pressure sensors represents a particularly advantageous application of the assembly and connection technology according to the present invention.

Various materials and also various connection technologies may fundamentally be used for the sensor element and carrier in the scope of the present invention. However, these are to be adapted to one another. Thus, it proven to be advantageous with respect to the use of the sensor system, according to the present invention at varying ambient temperatures if the coefficient of thermal expansion of the carrier material is adapted to the coefficient of thermal expansion of the sensor element. For example, glass, or ceramic carriers, which are both cost-effective and simple to process, fulfill this condition for sensor elements based on silicon.

In addition, through contacts in the form of metal pins or silicon through contacts may be embedded easily and reliably in these carrier materials. Silicon through contacts are advantageously metal plated on both sides for better electrical connection. Furthermore, it is advantageous that standard methods are available to produce a reliable bond between a silicon sensor element and a glass/ceramic carrier, such as anodic bonding or seal glass gluing with the aid of a suitable glass solder. The electrical connection between the sensor element and the through contacts of the carrier is advantageously created by thermal compression bonding. The glass/ceramic carrier may be made of a multilayer ceramic system, so that printed conductors may be guided parallel to the surface in the interior of the carrier, enclosed on both sides by carrier material. A special corrosion protection is possible as a result of these embedded printed conductors.

As already noted, sensor systems according to the present invention are particularly suitable for pressure detection. Exemplary embodiments for absolute pressure detection and relative pressure detection are explained in greater detail hereafter in connection with the figures.

The claimed method for manufacturing sensor systems of this type for pressure detection provides that firstly the surface of a semiconductor wafer is processed in order to produce circuit elements for signal detection, such as piezoresistors having electrical supply lines, in the sensor surface of a plurality of sensor elements. Micromechanical structures may also be generated in and/or below the surface of the semiconductor wafer in the scope of the surface processing of the semiconductor wafer, in particular caverns as reference volumes.

The sensor diaphragms are produced in that the semiconductor wafer is thinned down to diaphragm thickness starting from the rear side at least in an area of the sensor elements. This may be performed, for example, by appropriate structuring of the wafer rear side.

Independently of the processing of the semiconductor wafer, a glass/ceramic carrier substrate, which is provided with through contacts, is structured in order to produce reference volumes or pressure connection openings for a plurality of sensor elements. The processed surface of the semiconductor wafer is situated aligned on the structured glass/ceramic carrier and installed, the mechanical connection being created by anodic bonding or seal glass gluing and the electrical contact of the sensor elements to the through contacts of the carrier substrate being created simultaneously, i.e., in one installation step, by thermal compression bonding.

In a particularly advantageous variant of the method according to the present invention, the sensor diaphragms are only manufactured after the manufacturing of the composite made of semiconductor wafer and carrier substrate, in that the semiconductor wafer is thinned over its entire area down to diaphragm thickness in the composite with the glass/ceramic carrier. For this purpose, the semiconductor wafer may simply be ground down, for example, to an SOI layer functioning as a grind stop layer, which is particularly cost-effective.

The sensor systems are only isolated thereafter by cutting apart the composite made of semiconductor wafer and glass/ceramic carrier, for example, by sawing.

At least a part of the circuit elements in the surface of the individual sensor elements is capped by the carrier. The requirement for further protective measures after the isolation process is dispensed with for these circuit elements. In the event of corresponding assembly of the sensor system, further packaging of the sensor elements after the isolation may even be completely dispensed with. The sensor systems may be extremely miniaturized, in particular if an integrated compensation or analysis circuit is dispensed with.

As already explained above, there are various possibilities for advantageously implementing and refining the teaching of the exemplary embodiments and/or exemplary methods of the present invention. For this purpose, reference is made to the Patent Claims subordinate to the independent Patent Claims, on the one hand, and to the following description of multiple exemplary embodiments of the present invention on the basis of the figures, on the other hand.

### BRIEF DESCRIPTION OF THE DRAWINGS

FIG. 1 shows a schematic sectional view of a sensor system 10 according to the related art.

FIG. 2a shows a schematic sectional view of a sensor system 20 according to the present invention for absolute pressure detection.

FIG. 2b shows a schematic sectional view of the composite made of a processed semiconductor wafer and a carrier substrate before the isolation of sensor systems 20 shown in FIG. 2a.

FIG. 3 shows a schematic sectional view of a sensor system 30 according to the present invention for relative pressure detection.

FIG. 4 shows a schematic sectional view of a second sensor system 40 according to the present invention for absolute pressure detection.

FIG. 5a shows a schematic sectional view of a third sensor system 50 according to the present invention for absolute pressure detection.

FIG. 5b shows a schematic sectional view of the composite made of a processed semiconductor wafer and a carrier substrate before the isolation of sensor systems 50 shown in FIG. 5a.

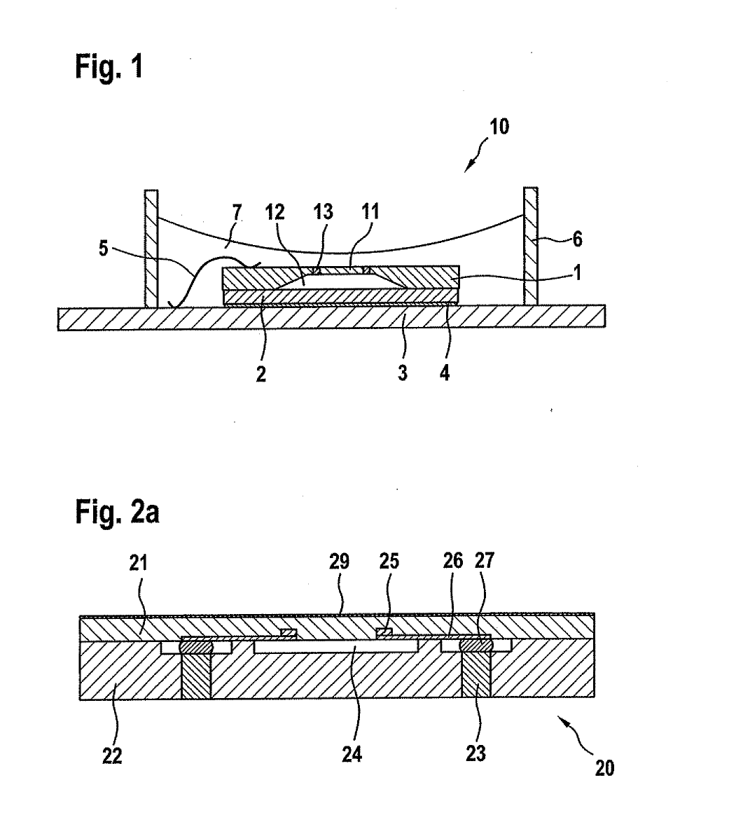

### DETAILED DESCRIPTION

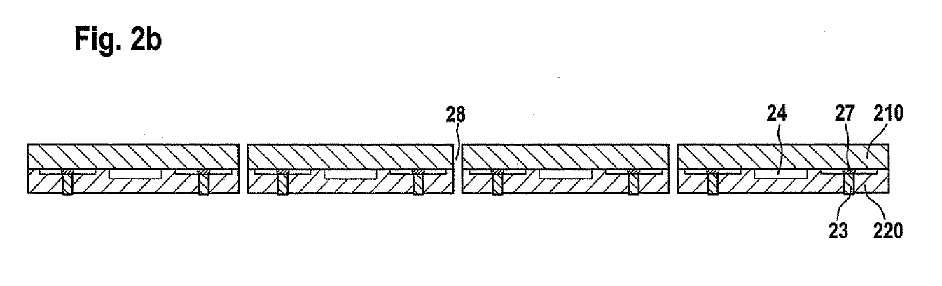

FIG. 2a shows a sensor system 20, made of a sensor element 21 and a carrier 22. Sensor system 20 is used for absolute pressure detection.

In the present exemplary embodiment, carrier 22 is a glass carrier having silicon through contacts 23, which are provided on both sides with metal plating for better contacting. A cavernous opening 24 is implemented in the surface of glass carrier 22 between through contacts 23.

Sensor element 21 is implemented here in the form of a silicon substrate which is thinned down to diaphragm thickness over its entire area, and which is installed upside down in flip-chip technology on glass carrier 22. Prior to the installation of sensor element 21, piezoresistive transducer elements 25 having highly doped electrical supply lines 26, which may be anodically bonded, were integrated into the surface of sensor element 21. Piezoresistive transducer elements 25 are situated in the active diaphragm area above cavernous opening 24 and electrical supply lines 26 are guided outward to through contacts 23.

The mechanical connection between sensor element 21 and glass carrier 22 was created by anodic bonding. Cavernous opening 24 was closed in a pressure-tight manner, so that a defined reference pressure prevails here. In the same installation step, the electrical connection between supply lines 26 and through contacts 23 was also created, in that the contact surfaces of sensor element 21 were connected using thermal compression bonding to the metal-plated contact pads of through contacts 23 of glass carrier 22, which were situated in a matching manner. For this purpose, high-melting-point solders were used, which, to avoid cavities, may be flux-free and compatible with electrical supply lines 26, which may be made of temperature-resistant alloys made of gold, platinum, palladium with tin or niobium for high-temperature applications. The supply lines are led via corresponding diffusion barriers at least in the silicon contact area. Depressions are implemented around the contacting pads of through contacts 23 in the surface of glass carrier 22, in order to receive solder bumps 27, which are bonded to the corresponding contact areas of sensor element 21 before the actual bonding procedure.

Transducer elements 25 of sensor element 21 may thus be electrically contacted via through contacts 23 from the rear side of glass carrier 22.

Sensor element 21 was advantageously only thinned after the production of the composite with glass carrier 22, and even before the isolation of sensor system 20 manufactured in the wafer composite, which is illustrated by FIG. 2b.

A glass wafer 220 having embedded highly doped silicon through contacts 23 is shown here, whose surface is structured so that a cavernous opening 24 is implemented between each two through contacts 23, which are spaced apart corresponding to the diaphragm dimensions.

Independently of glass wafer 220, circuit elements, piezoresistive transducer elements having electrical supply lines here, and a plurality of sensor elements 21 are integrated into the front side of a silicon wafer 210, the positions of these circuit elements being adapted to the configuration of through contacts 23 in glass wafer 220.

The processed front side of silicon wafer 210 was then anodically bonded against the structured surface of glass wafer 220. The requirement for the anodic bond is that the surface of glass wafer 220 is smooth, for example, polished, and the front side of silicon wafer 210 is smooth and unpassivated in the bond areas. In this manner, the circuit elements in the front side of silicon wafer 210 are capped by glass wafer 220. The electrical connections between the supply lines and through contacts 23 were also created during the bonding process, as previously explained.

In the exemplary embodiment described here, silicon wafer 210 was thinned over its entire area down to diaphragm thickness in the composite with glass wafer 220, an SOI layer being able to be used as the grind stop boundary. The isolation of the sensor systems is only performed thereafter by cost-effective sawing of the glass-silicon sandwich, which is indicated here by sawing trenches 28. Sensor system 20 shown in FIG. 2a is the result of this isolation process.

In the case of sensor system 20, the pressure is applied to the unprocessed rear side of sensor element 21, so that the measurement medium does not come into contact with circuit elements 25 and 26 on the front side of sensor element 21, which proves to be advantageous in particular in the case of aggressive measuring media. The thus implemented corrosion, protection of circuit elements 25 and 26 is also supplemented by a non-stick layer 29 on the open silicon and glass surfaces, by which deposits on sensor system 20 are prevented and the effects of icing may also be reduced. For high-usage temperatures, for example, non-stick layers made of silicon carbide or silicon nitride are suitable. Silanization of the surfaces is suitable for low-usage temperatures.

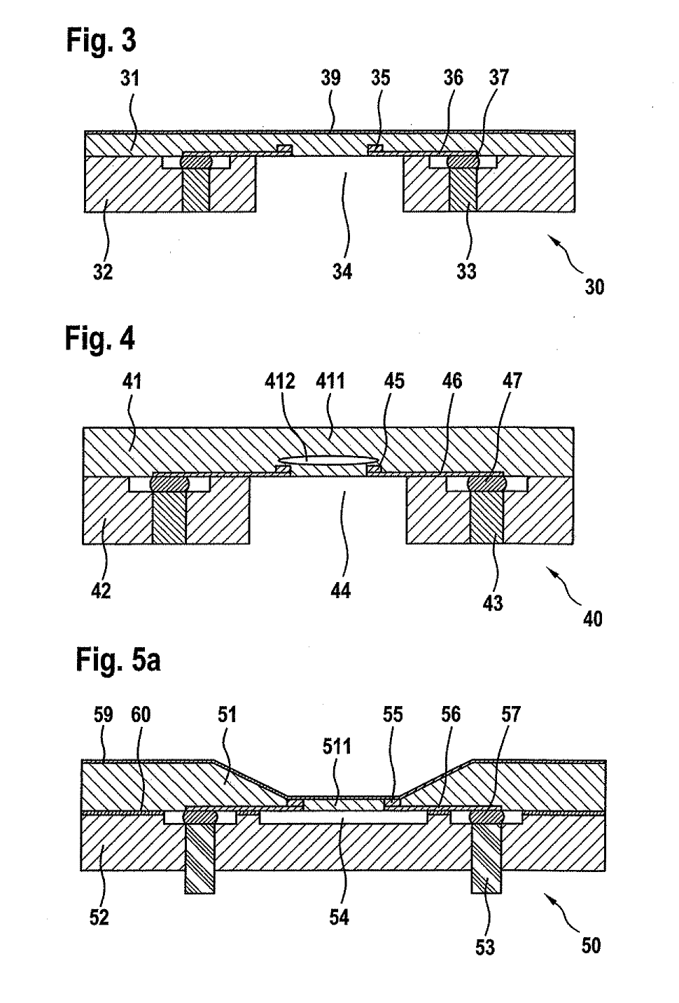

Sensor system 30 shown in FIG. 3 essentially corresponds to sensor system 20, but is designed differently thereto for relative pressure measurements. For this purpose, sensor system 30 includes a sensor element 31 which—like sensor element 21—is implemented in the form of a silicon substrate thinned down to diaphragm thickness over its entire area. The diaphragm deformations are also detected here with the aid of piezoresistive transducer elements 35 having highly doped supply lines 36 which may be anodically bonded, and which are integrated into the top side of sensor element 31. Sensor element 31 is installed upside down in flip-chip technology on a glass carrier 32 according to the exemplary embodiments and/or exemplary methods of, the present invention. In contrast to glass carrier 22, this glass carrier is provided with a through opening 34 as a pressure connection opening, so that the active diaphragm area of sensor element 31 spanning through opening 34 may have pressure applied to it on both sides. Piezoresistive transducer elements 35 are situated in the active diaphragm area over through opening 34 and electrical supply lines 36 are led outward, where they are connected via solder bumps 37 to through contacts 33, which are embedded in glass carrier 32. As in the case of sensor system 20, the mechanical connection between sensor element 31 and glass carrier 32 was created by anodic bonding. Two concentric connection areas result. One connection area is located between through opening 34 and through contacts 33, and the second connection area extends outward from through contacts 33. These two connection areas enclose the metal-plated contact pads of through contacts 33 and protect them against corrosion. A non-stick layer 39 on the open surfaces of sensor element 31 and carrier 32 forms an additional layer.

A second exemplary embodiment of a sensor system 40 according to the present invention, which is intended for the absolute pressure measurement, is shown in FIG. 4. This sensor system includes a sensor element 41, in whose surface a diaphragm 411 was exposed by superficial micromechanical processing. Diaphragm 411 spans a closed cavern 412 in the substrate of sensor element 41, in which a defined reference pressure for the absolute pressure measurement prevails. Piezoresistive transducer elements 45 having electrical supply lines 46, which are led outward, are implemented in diaphragm 411. Sensor element 41 is installed in flip-chip technology on a glass carrier 42 having through contacts 43 and a through opening 44 as a pressure connection opening for diaphragm 411 and contacted via solder bumps 47. As in the case of sensor element 30, two connection areas, which are implemented concentrically to one another, also protect the contacting pads of through contacts 43 and parts of an integrated analysis circuit, which is optionally implemented on the surface of sensor element 41, against the attack of the measurement medium.

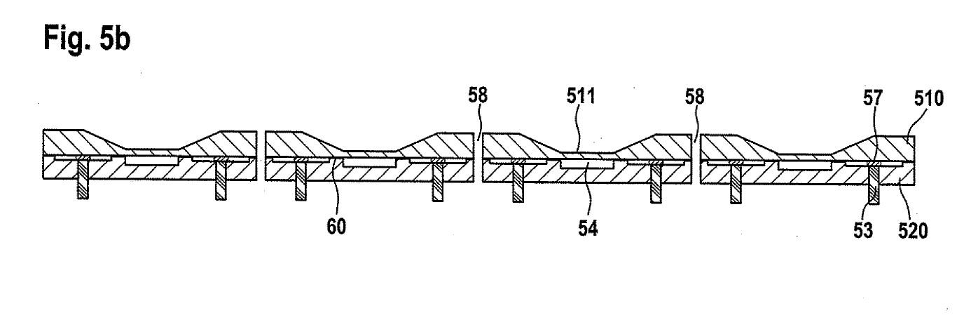

Sensor system 50 shown in FIG. 5a is also conceived for the absolute pressure measurements. It includes a sensor element 51, which is installed on a carrier 52 in flip-chip technology. As in the case of sensor element 20, carrier 52 is a glass or ceramic carrier having embedded through contacts 53, which are implemented here in the form of metal pins, however. Metal pins 53 open into depressions in the carrier top side, where they terminate flatly, and function on the carrier bottom side as contact pins for sensor system 50. A cavernous opening 54 is implemented in the carrier surface between metal pins 53 and is closed in a pressure-tight manner by sensor element 51, so that a defined reference pressure for the absolute pressure measurement prevails within cavernous opening 54.

Sensor element 51 is a silicon chip, in whose top side a diaphragm 511 is implemented. This diaphragm 511 was exposed by structuring the chip rear side and accordingly has pressure applied to it via the chip rear side. The diaphragm deformations are also detected here with the aid of piezoresistive transducer elements 55, which were integrated together with highly doped electrical supply lines 56 in the diaphragm surface. Piezoresistors 55 are equipped with a diffusion barrier and are thus high-temperature resistant.

Supply lines 56 are implemented, for example, in the form of polysilicon, gold, or platinum printed conductors.

The mechanical connection between the top side of sensor element 51 and the carrier top side was implemented here in the form of a glass-glued joint. The glass solder used for this purpose is just as high-temperature-capable as sensor element 51, carrier 52, and solder bumps 57, which are situated in the depressions in the carrier top side and via which the electrical connection is created between supply lines 56 of sensor element 51 and metal pins 53 of carrier 52.

Because of the high-temperature resistance of above-described sensor system 50, additional heating resistors via which the sensor system may be heated in a targeted manner may be embedded in the glass carrier, for example. Organic deposits on the sensor system, which may occur after a long operating time in spite of non-stick layer 59, may thus be burned away.

The composite shown in FIG. 5b made of a processed silicon wafer 510 and a glass wafer 520 illustrates the manufacturing of sensor system 50 shown in FIG. 5a.

Metal pins 53 are embedded as through contacts in glass wafer 520. In addition, the surface of glass wafer 520 is structured so that a cavernous opening 54 is implemented between each two metal pins 53, which are spaced apart corresponding to the diaphragm dimensions.

In the exemplary embodiment shown here, the front side of silicon wafer 510 was processed in order to integrate circuit elements, piezoresistive transducer elements having electrical supply lines, and a plurality of sensor elements here, the positions of these circuit elements being adapted to the configuration of metal pins 53 and cavernous openings 54. In addition, the rear side of silicon wafer 510 was structured by potassium hydroxide etching, diaphragms 511 of individual sensor elements 51 being exposed.

The front side of silicon wafer 510 was then glued on the structured surface of glass wafer 520. This glued joint was created with the aid of a glass solder layer 60. The electrical connections between the supply lines and metal pins 53 were also created in the same installation step.

Silicon wafer 510 may then also be thinned further over its entire area, for example, by grinding, in the composite with glass wafer 520.

The isolation of the sensor systems by cost-effective sawing of the glass silicon sandwich is only performed thereafter, which is indicated here by sawing trenches 58. Sensor system 50 shown in FIG. 5a is the result of this isolation process.

The assembly and connection technology, which is also explained above on the basis of the examples, allows the implementation of very cost-effective, highly miniaturized sensor systems, which are insensitive to installation stress and are suitable for high temperatures, and which may be processed further in manifold ways, for example, by conductive gluing or soldering directly onto a circuit board. The sensor systems according to the present invention are therefore particularly suitable for use in rough measuring environments in the event of very restricted space conditions. The assembly and connection technology according to the present invention may advantageously be used, for example, for implementing absolute pressure sensors in the exhaust train of vehicles, differential pressure sensors in diesel particulate filters or catalytic converters, combustion chamber pressure sensors, pressure sensors in particulate filters of solid fuel heating systems, pressure sensors for turbines and media-resistant pressure sensors in liquids for measuring fill levels, flow rates, or pressure, for example, in oil pressure sensors.

What is claimed is:

1. A sensor system, comprising:
a sensor element having circuit elements integrated into its top side; and
a carrier for the sensor element;
wherein the carrier has through contacts, and
wherein the sensor element is installed with flip-chip technology on the carrier, so that the top side of the sensor element is at least regionally capped by the carrier and the circuit elements of the sensor element can be electrically contacted from a rear side of the carrier via the through contacts.

2. The sensor system of claim 1, wherein a coefficient of thermal expansion of the carrier material is adapted to a coefficient of thermal expansion of the sensor element.

3. The sensor system of claim 1, wherein the sensor element is manufactured starting from a silicon substrate, and wherein the carrier is a glass/ceramic carrier.

4. The sensor system of claim 3, wherein the through contacts are implemented in the form of silicon through contacts, which are at least one of (i) metal-plated on both sides and (ii) metal pins.

5. The sensor system of claim 3, wherein the sensor element and the carrier are mechanically connected one of by anodic bonding and by seal glass gluing using glass solder.

6. The sensor system of claim 3, wherein the electrical connection between the sensor element and the through contacts of the carrier is created by thermal compression bonding.

7. The sensor system of claim 1, wherein the sensor system is for absolute pressure detection, wherein the sensor element is thinned down to a diaphragm thickness at least in a diaphragm area, and wherein a cavern, which is closed in a pressure-tight manner by the sensor element and thus functions as a reference volume, is implemented in a carrier surface below the diaphragm area.

8. The sensor system of claim 1, wherein the sensor system is for absolute pressure detection, wherein a diaphragm, which spans a closed cavern in the sensor element functioning as a reference volume, is implemented in a surface of the sensor element installed on the carrier, and wherein a pressure connection opening for applying pressure to the diaphragm is implemented in the carrier.

9. The sensor system of claim 1, wherein the sensor system is for relative pressure detection, wherein the sensor element is thinned down to diaphragm thickness at least in a diaphragm area, and wherein a pressure connection opening for applying pressure to the diaphragm is implemented in the carrier.

10. The sensor system of claim 7, wherein high-temperature-resistant piezoresistors having a diffusion barrier are integrated into the top side of the sensor element to detect diaphragm deformations.

11. A method for manufacturing a sensor system, the method comprising:
processing a surface of a semiconductor wafer to produce circuit elements in a sensor surface of a plurality of sensor elements;
thinning down the semiconductor wafer to diaphragm thickness at least in an area of the sensor elements starting from the rear side;
structuring a glass/ceramic carrier substrate having through contacts to produce one of reference volumes and pressure connection openings for a plurality of sensor elements;
situating and installing the processed surface of the semiconductor wafer so that it is aligned on the structured glass/ceramic carrier, wherein the mechanical connection is created by one of anodic bonding and seal glass gluing, and wherein the electrical contact of the sensor elements to the through contacts of the carrier substrate is created simultaneously by thermal compression bonding; and
isolating the sensor systems by cutting apart the composite made of at least one of the semiconductor wafer and the glass/ceramic carrier;
wherein the sensor element has the circuit elements integrated into its top side, and wherein the carrier for the sensor element has the through contacts, and
wherein the sensor element is installed with flip-chip technology on the carrier, so that the top side of the sensor element is at least regionally capped by the carrier and the circuit elements of the sensor element can be electrically contacted from a rear side of the carrier via the through contacts.

12. The method of claim 11, wherein micromechanical structures are also generated at least one of in and below the surface of the semiconductor wafer, in caverns as reference volumes, when the surface of the semiconductor wafer is processed.

13. The method of claim 11, wherein the semiconductor wafer is thinned down to diaphragm thickness over its entire area in the composite with the glass/ceramic carrier.

14. The method of claim 11, wherein an isolation of the sensor systems is provided by sawing.

15. The sensor system of claim 8, wherein high-temperature-resistant piezoresistors having a diffusion barrier are integrated into the top side of the sensor element to detect diaphragm deformations.

16. The sensor system of claim 9, wherein high-temperature-resistant piezoresistors having a diffusion barrier are integrated into the top side of the sensor element to detect diaphragm deformations.
